(19) United States
(12) Patent Application Publication
(10) Pub. No.: US 2023/0366923 A1
(43) Pub. Date: Nov. 16, 2023

(54) REDUCING DIGITAL TEMPERATURE SENSOR ERROR WITH MACHINE LEARNING

(71) Applicant: Intel Corporation, Santa Clara, CA (US)

(72) Inventors: Sarah Shahraini, Newcastle, WA (US); Mohamed Abdelmoneum, Portland, OR (US); Richard Dorrance, Hillsboro, OR (US); Renzhi Liu, Portland, OR (US); Eduardo Alban, Hillsboro, OR (US)

(21) Appl. No.: 18/358,458

(22) Filed: Jul. 25, 2023

(51) Int. Cl. G01R 31/28; G06N 20/00

(52) U.S. Cl. CPC G01R 31/2874; G01R 31/2879; G06N 20/00

(57) ABSTRACT

Systems, apparatuses and methods may provide for chip technology including a memory structure having stored weights associated with a machine learning (ML) model, a plurality of digital temperature sensors to generate readings, and a classification engine to retrieve the stored weights from the memory structure and adjust the readings from the plurality of digital temperature sensors based on the weights and electrical parameters associated with the chip.

### TECHNICAL FIELD

Embodiments generally relate to digital temperature measurements. More particularly, embodiments relate to reducing digital temperature sensor error with machine learning technology.

### BACKGROUND

Integrated circuit (IC) chips are typically designed to operate within a specific temperature range to ensure proper functionality and preserve the lifespan of the IC chip. Temperature sensors internal to the chip may be used to determine whether the chip is remaining within the margins of the temperature range. The accuracy of the temperature sensors, however, directly impacts this thermal margin determination. Chip designers may implement thermal guard bands during many design stages, with control circuitry in place to shut down the circuit or reduce the clock frequency if the temperature sensors detect temperatures at the upper temperature margin, thereby limiting chip performance. This issue may be particularly challenging for advanced node chips and continuous running applications, such as artificial intelligence (AI) based servers in data centers.

### BRIEF DESCRIPTION OF THE DRAWINGS

The various advantages of the embodiments will become apparent to one skilled in the art by reading the following specification and appended claims, and by referencing the following drawings, in which:

FIG. 1 is a plan view of an example of an intra-die (e.g., in-die, within-die) variation (IDV) template and a digital temperature sensor (DTS) template for a chip according to an embodiment;

FIG. 2 is a block diagram of an example of a training operation according to an embodiment;

FIG. 3 is a block diagram of an example of a real-time error correction according to an embodiment;

FIG. 4 is a set of comparative charts of an example of a conventional error distribution histogram and an enhanced error distribution histogram according to an embodiment;

FIG. 5 is a flowchart of an example of a method of conducting a training operation according to an embodiment;

FIG. 6 is a flowchart of an example of a method of conducting real-time error corrections according to an embodiment;

FIG. 7 is a block diagram of an example of a performance-enhanced computing system according to an embodiment;

FIG. 8 is an illustration of an example of a semiconductor package apparatus according to an embodiment;

FIG. 9 is a block diagram of an example of a processor according to an embodiment; and

FIG. 10 is a block diagram of an example of a multi-processor based computing system according to an embodiment.

### DETAILED DESCRIPTION

The technology described herein increases the accuracy of temperature sensors, without the need for High Volume Manufacturing (HVM) calibration. By leveraging machine learning techniques, embodiments can minimize the impact of fabrication process variations, environmental variations and other sources of noise, resulting in highly accurate temperature readings.

The sources of digital temperature sensor (DTS) error can be categorized into global process variation, in-die process gradient incurred variation, and random mismatch. To accurately predict and reduce these sources of error, the technology described herein leverages E-test data and intra-die variation (IDV) data to learn the DTS error due to global process variation and in-die gradient error.

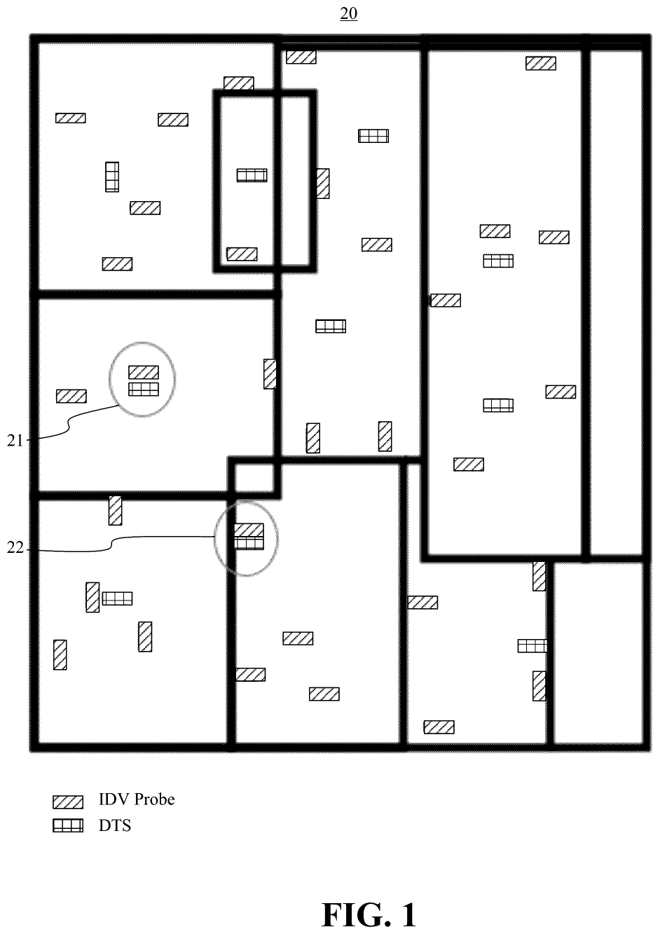

Turning now to FIG. 1, an integrated circuit (IC) chip 20 (e.g., die, package and/or semiconductor apparatus) is shown, wherein the chip is overlaid with a digital temperature sensor (DTS) template and an intra-die variation (IDV) template. The DTS template illustrates the relative positions and orientations of a plurality of digital temperature sensors that are used to monitor temperatures on the chip 20. The IDV template illustrates the relative positions and orientations of a plurality of IDV probes that are used to generate electrical parameters associated with the chip.

More particularly, each IDV probe (e.g., process monitoring circuitry) may include a ring oscillator made up of specific number of inverters to emulate random and systematic variations. The ring oscillator has specific channel dimensions to match the average device parameters of devices (e.g., N-type transistors, P-type transistors, etc.) on the chip 20. The IDV probes may also include other types of sensors (e.g., voltage sensors, process monitors, etc.) to collect IDV data. The IDV probes can be grouped into clusters (e.g., functional unit blocks/FUBs). Each cluster can also include a support circuit to provide isolation and frequency division of each of the ring oscillators. The oscillator frequency, which is counted using an on-chip frequency counter, can be downloaded into a tester.

Because an oscillator runs at a frequency determined by local device parameters and environmental values, measured frequencies can be used to form a spatial map of the chip 20 and compute the statistics of the systematic and random speed variations across the chip 20, the associated wafer and/or the associated lot. In one example, the IDV probes monitor process speed and variation due to such parameters as diffusion width, channel length, and threshold. Additionally, the IDV probes may be activated while the chip 20 is either “quiet” or operating. As will be discussed in greater detail below, other electrical parameters such as, for example, electrical test (E-test) data (e.g., indicating short circuits, interruptions, incorrect and broken conductors, etc., relative to a net list), current leakage (e.g., I_{leakage}) data, voltage threshold (e.g., Vₜ) data, etc., can be monitored and/or collected for the chip 20.

In the illustrated example, a first location 21 and a second location 22 on the chip 20 are areas where an IDV probe and a DTS are positioned adjacent to one another. By placing DTS and IDV probes at the locations 21, 22 near one another, it is possible to reduce the DTS error further, resulting in more accurate temperature readings.

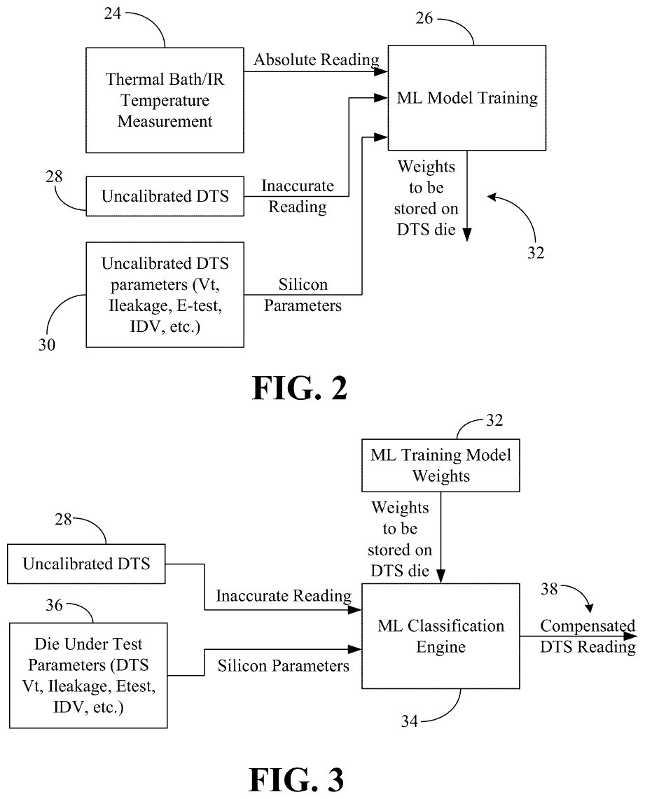

FIG. 2 shows a training operation in which an IC chip is placed in an oil bath to ensure that all sensors 28 are at the same temperature (e.g., eliminating any unwanted gradients). The physical location of the sensors 28, E-test data sources, IDV probe data, and thermal diode data are obtained in a measurement 24 at, for example, 5° C./10° C. intervals. The temperature in the oil bath is used as a label for each training example, and each sensor 28 at each temperature is a separate training example. Alternatives to the oil bath include a heating probe station, although the performance of such a solution may be dependent on the temperature gradient on the probe station plate. In one example, multiple chips, over different process corners, are tested to create a comprehensive training set that enables an ML model training 26 to learn the behavior of the sensors for different scenarios. Synthetic data can also be added to the training set to speed up data collection and increase the final accuracy. Additionally, a thermal model of the topology can be simulated to learn the temperature impacts of different components on the chip (e.g., a large inductor could skew the measurement more than cache memory, or the distance from an active/unactive central processing unit/CPU core might produce gradients), helping the neural network (NN) model include a “map” of the chip and sensor 28 locations to improve temperature accuracy.

More particularly, an ML model, such as a deep neural network (DNN), can be trained using absolute readings from the thermal bath/IR (infrared) temperature measurement 24, inaccurate readings from the uncalibrated sensors 28, and electrical parameters 30 such as voltage threshold, current leakage, E-test data, IDV data, etc., to learn a model that predicts the DTS error. Thus, the model has the capability to take into account both global process variation and in-die process gradient errors. In the illustrated example, the sensors 28 and the electrical parameters are uncalibrated. The weights 32 learned during the ML model training 26 can be stored and used in real-time correction operations. The model is not limited to a DNN and any ML model can be learned in the illustrated training operation.

FIG. 3 shows a real-time error correction in which the trained ML model weights 32 are retrieved from a memory structure (e.g., fuses, read only memory/ROM) on the chip and an on-chip classification/prediction engine 34 (e.g., including logic instructions, configurable logic, fixed-functionality hardware logic, etc., or any combination thereof) predicts the DTS error for each sensor 28 in real-time. In an embodiment, the engine 34 uses electrical (e.g., die under test) parameters 36 of the sensor 28, such as E-test data, IDV data, current leakage, and voltage threshold, as inputs to predict the DTS error. The predicted error is then used to compensate for the DTS error and improve the temperature accuracy of the sensor.

In one example, the classification/prediction engine 34 is implemented using various hardware solutions, such as a dedicated hardware block. The engine 34 uses the pre-trained ML model weights 32 to perform the DTS error prediction, and the predicted error is used to adjust the temperature readings from each sensor 28. The result is a compensated DTS reading 38, which is a more accurate temperature measurement across the chip, without the need for HVM calibration. In an embodiment, the real-time correction operation is performed continuously during the operation of the chip, ensuring that the temperature accuracy of the sensors 28 remains consistent over time and under different operating conditions.

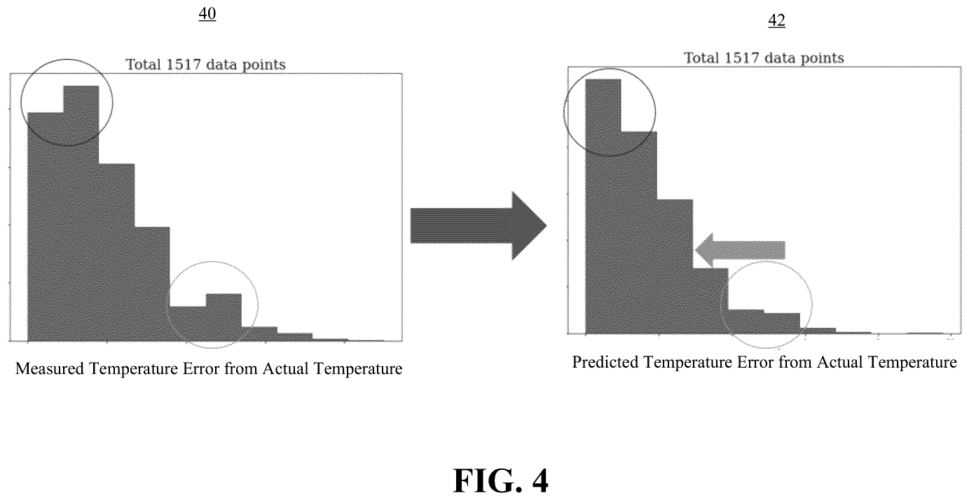

FIG. 4 shows a conventional error distribution histogram 40 and an enhanced error distribution histogram 42 for an experiment that was conducted to assess the feasibility of the technology described herein using a relatively restricted dataset. The dataset included data for only seven dies from one wafer, which provided DTS raw readings at six different temperatures (25° C., 50° C., 70° C., 80° C., 100° C., and 110° C.) and IDV data at only −10° C. IDV and DTS data, however, for all temperatures, physical location data, and E-test data were not available. Despite the limited data, a 5-layer neural network was trained on 60% of the data available and 40% of the data was used to test the ML model trained. The findings revealed that accuracy was improved approximately for 65% of the sensors. As shown in the error distribution histogram 40, 42, the number of sensors with a 1-degree error increased from below 400 units to over 500 units. Although the improvements may be small, given the scarcity of data available, illustrated results confirm that the ML technology described herein predicts DTS error accurately.

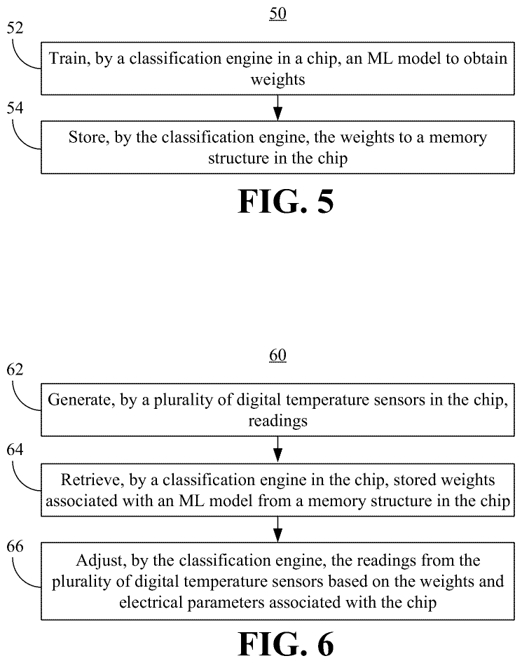

FIG. 5 shows a method 50 of conducting a training operation. The method 50 may generally be implemented in a chip such as, for example, the IC chip 20 (FIG. 1) and/or a classification engine such as, for example, the ML classification engine 34 (FIG. 3), already discussed. More particularly, the method 50 may be implemented in one or more modules as a set of logic instructions stored in a machine- or computer-readable storage medium such as random access memory (RAM), read only memory (ROM), programmable ROM (PROM), firmware, flash memory, etc., in hardware (e.g., configurable logic, fixed-functionality logic), or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Computer program code to carry out operations shown in the method 50 can be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 52 trains, by a classification engine in a chip, an ML model to obtain weights. Block 52 may train the ML model based on absolute readings associated with a thermal bath measurement, inaccurate readings from uncalibrated sensors, and uncalibrated electrical parameters obtained while the chip is in the thermal bath. In one example, block 52 is conducted iteratively and/or repeatedly until the weights cause the ML model to converge on a suitable level of accuracy and/or error. Block 54 stores, by the classification engine, the weights to a memory structure in the chip. The memory structure may include fuses, ROM, etc., or any combination thereof.

FIG. 6 shows a method 60 of conducting real-time error corrections. The method 60 may generally be implemented in a chip such as, for example, the IC chip 20 (FIG. 1), sensors such as, for example, the sensors 28 (FIG. 3), and/or a classification engine such as, for example, the ML classification engine 34 (FIG. 3), already discussed.

More particularly, the method 60 may be implemented in one or more modules as a set of logic instructions stored in a machine- or computer-readable storage medium such as RAM, ROM, PROM, firmware, flash memory, etc., in hardware, or any combination thereof.

Processing block 62 generates, by a plurality of digital temperature sensors in a chip, readings. In an embodiment, one or more of the readings are inaccurate due to global process variation, in-die process gradient incurred variation, random mismatch, and so forth. Block 64 retrieves, by a classification engine in the chip, stored weights associated with an ML model from a memory structure in the chip. In an embodiment, the stored weights result from execution of a method such as, for example, the method 50 (FIG. 5), already discussed. Block 66 adjusts, by the classification engine, the readings from the plurality of digital temperature sensors based on the weights and electrical parameters (e.g., E-test data, IDV data, current leakage, and voltage threshold) associated with the chip. In one example, the electrical parameters and the plurality of digital temperature sensors are uncalibrated (e.g., HVM 2-point calibration is bypassed). The method 60 may also include generating, by a plurality of IDV probes, one or more of the electrical parameters. In such a case, one or more of the plurality of IDV probes can be positioned adjacent to one or more of the plurality of digital temperature sensors to increase accuracy.

The method 60 and the method 50 (FIG. 5) therefore enhance performance at least to the extent that training the ML model to obtain the weights and subsequently using the weights to make real-time error corrections significantly reduces the DTS error (e.g., from ±5° C. to ±1° C.). Such a reduction in error decreases the thermal margin to be considered in the design phase and improves overall performance. The method 60 and the method 50 (FIG. 5) also eliminate the need for HVM calibration, which simplifies the manufacturing process and reduces costs.

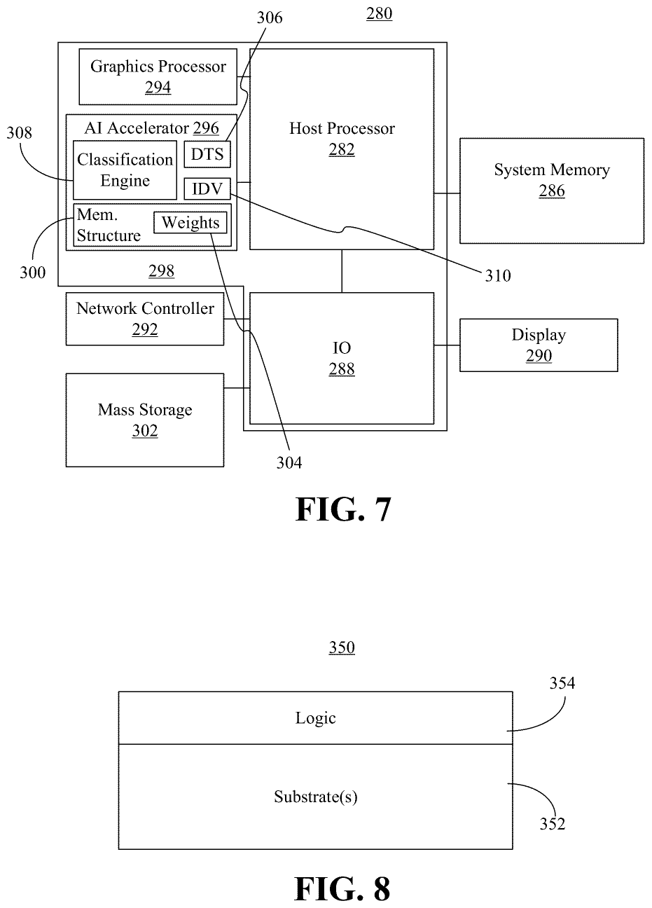

Turning now to FIG. 7, a performance-enhanced computing system 280 is shown. The system 280 may generally be part of an electronic device/platform having computing functionality (e.g., personal digital assistant/PDA, notebook computer, tablet computer, convertible tablet, edge node, server, cloud computing infrastructure), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM including a plurality of dynamic RAMs/DRAMs). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 (e.g., specialized processor including logic instructions, configurable logic, fixed-functionality hardware logic, etc., or any combination thereof) into a system on chip (SoC) 298.

In an embodiment, the AI accelerator 296 is incorporated onto a chip such as, for example, the chip 20 (FIG. 1). Thus, logic of the AI accelerator 296 may include a memory structure 300 (e.g., fuses, ROM) including stored weights 304 associated with an ML model, a plurality of digital temperature sensors 306 (e.g., uncalibrated DTS's) to generate readings (e.g., including one or more inaccurate readings), and a classification engine 308 to retrieve the stored weights 304 from the memory structure 300 and adjust the readings from the plurality of digital temperature sensors 306 based on the weights 304 and electrical parameters (e.g., uncalibrated electrical parameters) associated with the SoC 298. In one example, logic of the AI accelerator 296 includes a plurality of IDV probes 310 to generate one or more of the electrical parameters. In such a case, one or more of the IDV probes can be positioned adjacent to one or more of the digital temperature sensors 306.

The computing system 280 is therefore considered performance-enhanced at least to the extent that training the ML model to obtain the weights and subsequently using the weights to make real-time error corrections significantly reduces the DTS error (e.g., from ±5° C. to ±1° C.). Such a reduction in error decreases the thermal margin to be considered in the design phase and improves overall performance. The computing system 280 also eliminates the need for HVM calibration, which simplifies the manufacturing process and reduces costs.

FIG. 8 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of method 50 (FIG. 5) and/or the method 60 (FIG. 6), already discussed. The logic 354 may also be incorporated into the AI accelerator 296 (FIG. 7, e.g., to include a memory structure, a plurality of digital temperature sensors, a classification engine, a plurality of IDV probes, etc.).

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

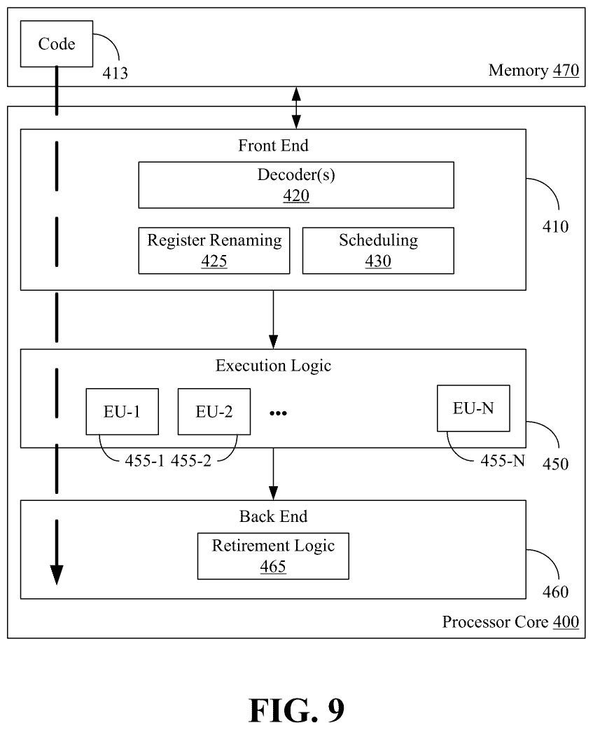

FIG. 9 illustrates a processor core 400 according to one embodiment. The processor core 400 may be the core for any type of processor, such as a micro-processor, an embedded processor, a digital signal processor (DSP), a network processor, or other device to execute code. Although only one processor core 400 is illustrated in FIG. 9, a processing element may alternatively include more than one of the processor core 400 illustrated in FIG. 9. The processor core 400 may be a single-threaded core or, for at least one embodiment, the processor core 400 may be multithreaded in that it may include more than one hardware thread context (or “logical processor”) per core.

FIG. 9 also illustrates a memory 470 coupled to the processor core 400. The memory 470 may be any of a wide variety of memories (including various layers of memory hierarchy) as are known or otherwise available to those of skill in the art. The memory 470 may include one or more code 413 instruction(s) to be executed by the processor core 400, wherein the code 413 may implement the method 50 (FIG. 5) and/or the method 60 (FIG. 6), already discussed. The processor core 400 follows a program sequence of instructions indicated by the code 413. Each instruction may enter a front end portion 410 and be processed by one or more decoders 420. The decoder 420 may generate as its output a micro operation such as a fixed width micro operation in a predefined format, or may generate other instructions, microinstructions, or control signals which reflect the original code instruction. The illustrated front end portion 410 also includes register renaming logic 425 and scheduling logic 430, which generally allocate resources and queue the operation corresponding to the convert instruction for execution.

The processor core 400 is shown including execution logic 450 having a set of execution units 455-1 through 455-N. Some embodiments may include a number of execution units dedicated to specific functions or sets of functions. Other embodiments may include only one execution unit or one execution unit that can perform a particular function. The illustrated execution logic 450 performs the operations specified by code instructions.

After completion of execution of the operations specified by the code instructions, back end logic 460 retires the instructions of the code 413. In one embodiment, the processor core 400 allows out of order execution but requires in order retirement of instructions. Retirement logic 465 may take a variety of forms as known to those of skill in the art (e.g., re-order buffers or the like). In this manner, the processor core 400 is transformed during execution of the code 413, at least in terms of the output generated by the decoder, the hardware registers and tables utilized by the register renaming logic 425, and any registers (not shown) modified by the execution logic 450.

Although not illustrated in FIG. 9, a processing element may include other elements on chip with the processor core 400. For example, a processing element may include memory control logic along with the processor core 400. The processing element may include I/O control logic and/or may include I/O control logic integrated with memory control logic. The processing element may also include one or more caches.

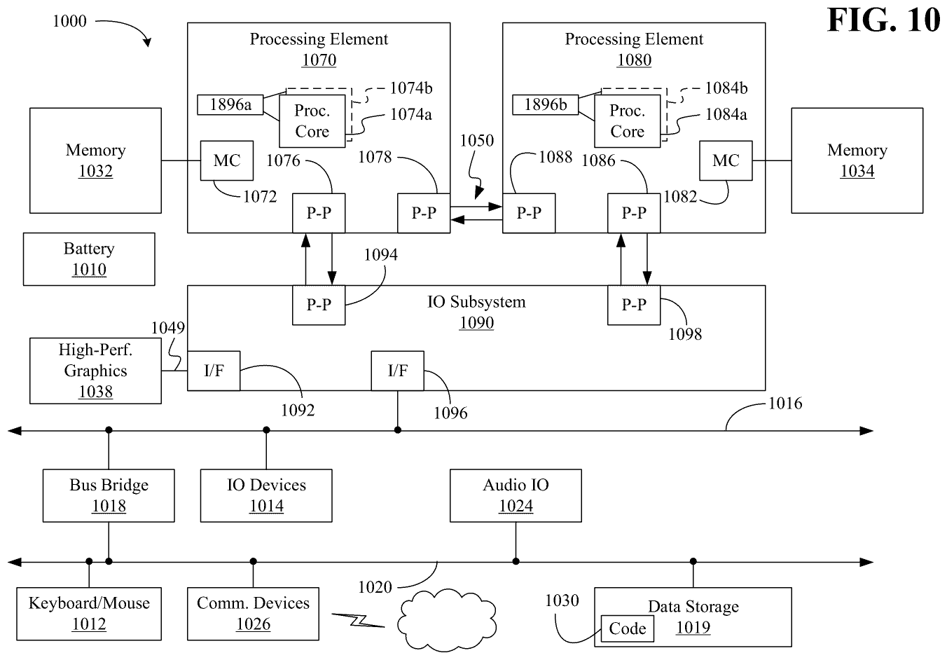

Referring now to FIG. 10, shown is a block diagram of a computing system 1000 embodiment in accordance with an embodiment. Shown in FIG. 10 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood that any or all of the interconnects illustrated in FIG. 10 may be implemented as a multi-drop bus rather than point-to-point interconnect.

As shown in FIG. 10, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner similar to that discussed above in connection with FIG. 9.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments are not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 10, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 10, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments are not so limited.

As shown in FIG. 10, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the method 50 (FIG. 5) and/or the method 60 (FIG. 6), already discussed. Further, an audio I/O 1024 may be coupled to second bus 1020 and a battery 1010 may supply power to the computing system 1000.

Note that other embodiments are contemplated. For example, instead of the point-to-point architecture of FIG. 10, a system may implement a multi-drop bus or another such communication topology. Also, the elements of FIG. 10 may alternatively be partitioned using more or fewer integrated chips than shown in FIG. 10.

### ADDITIONAL NOTES AND EXAMPLES

Example 1 includes a performance-enhanced computing system comprising a network controller and a chip comprising logic coupled to one or more substrates, wherein the logic is implemented at least partly in one or more of configurable or fixed-functionality hardware, the logic including a memory structure including stored weights associated with a machine learning (ML) model, a plurality of digital temperature sensors to generate readings, and a classification engine to retrieve the stored weights from the memory structure and adjust the readings from the plurality of digital temperature sensors based on the weights and electrical parameters associated with the chip.

Example 2 includes the computing system of Example 1, wherein the electrical parameters and the plurality of digital temperature sensors are to be uncalibrated.

Example 3 includes the computing system of Example 1, wherein the logic further includes a plurality of intra-die variation (IDV) probes to generate one or more of the electrical parameters.

Example 4 includes the computing system of Example 3, wherein one or more of the plurality of IDV probes are positioned adjacent to one or more of the plurality of digital temperature sensors.

Example 5 includes the computing system of Example 1, wherein the classification engine is further to train the ML model to obtain the weights, and store the weights to the memory structure.

Example 6 includes the computing system of any one of Examples 1 to 5, wherein the memory structure includes one or more of fuses or a read-only memory.

Example 7 includes a semiconductor apparatus comprising one or more substrates, and logic coupled to the one or more substrates, wherein the logic is implemented at least partly in one or more of configurable or fixed-functionality hardware, the logic including a memory structure including stored weights associated with a machine learning (ML) model, a plurality of digital temperature sensors to generate readings, and a classification engine to retrieve the stored weights from the memory structure and adjust the readings from the plurality of digital temperature sensors based on the weights and electrical parameters associated with the semiconductor apparatus.

Example 8 includes the semiconductor apparatus of Example 7, wherein the electrical parameters and the plurality of digital temperature sensors are to be uncalibrated.

Example 9 includes the semiconductor apparatus of Example 7, wherein the logic further includes a plurality of intra-die variation (IDV) probes to generate one or more of the electrical parameters.

Example 10 includes the semiconductor apparatus of Example 9, wherein one or more of the plurality of IDV probes are positioned adjacent to one or more of the plurality of digital temperature sensors.

Example 11 includes the semiconductor apparatus of Example 7, wherein the classification engine is further to train the ML model to obtain the weights, and store the weights to the memory structure.

Example 12 includes the semiconductor apparatus of any one of Examples 7 to 11, wherein the memory structure includes fuses.

Example 13 includes the semiconductor apparatus of any one of Examples 7 to 12, wherein the memory structure includes a read-only memory.

Example 14 includes the semiconductor apparatus of any one of Examples 7 to 12, wherein the logic coupled to the one or more substrates includes transistor channel regions that are positioned within the one or more substrates.

Example 15 includes a method of operating a chip, the method comprising generating, by a plurality of digital temperature sensors in the chip, readings, retrieving, by a classification engine in the chip, stored weights associated with a machine learning (ML) model from a memory structure in the chip, and adjusting, by the classification engine, the readings from the plurality of digital temperature sensors based on the weights and electrical parameters associated with the chip.

Example 16 includes the method of Example 15, wherein the electrical parameters and the plurality of digital temperature sensors are uncalibrated.

Example 17 includes the method of Example 15, further including generating, by a plurality of intra-die variation (IDV) probes, one or more of the electrical parameters.

Example 18 includes the method of Example 17, wherein one or more of the plurality of IDV probes are positioned adjacent to one or more of the plurality of digital temperature sensors.

Example 19 includes the method of Example 15, further including training, by the classification engine, the ML model to obtain the weights, and storing, by the classification engine, the weights to the memory structure.

Example 20 includes the method of any one of Examples 15 to 19, wherein the memory structure includes one or more of fuses or a read-only memory.

Example 21 includes an apparatus comprising means for performing the method of any one of Examples 15 to 20.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller; and
a chip comprising logic coupled to one or more substrates, wherein the logic is implemented at least partly in one or more of configurable or fixed-functionality hardware, the logic including:
a memory structure including stored weights associated with a machine learning (ML) model,
a plurality of digital temperature sensors to generate readings, and
a classification engine to retrieve the stored weights from the memory structure and adjust the readings from the plurality of digital temperature sensors based on the weights and electrical parameters associated with the chip.

2. The computing system of claim 1, wherein the electrical parameters and the plurality of digital temperature sensors are to be uncalibrated.

3. The computing system of claim 1, wherein the logic further includes a plurality of intra-die variation (IDV) probes to generate one or more of the electrical parameters.

4. The computing system of claim 3, wherein one or more of the plurality of IDV probes are positioned adjacent to one or more of the plurality of digital temperature sensors.

5. The computing system of claim 1, wherein the classification engine is further to:
train the ML model to obtain the weights; and
store the weights to the memory structure.

6. The computing system of claim 1, wherein the memory structure includes one or more of fuses or a read-only memory.

7. A semiconductor apparatus comprising:
one or more substrates; and
logic coupled to the one or more substrates, wherein the logic is implemented at least partly in one or more of configurable or fixed-functionality hardware, the logic including:
a memory structure including stored weights associated with a machine learning (ML) model,
a plurality of digital temperature sensors to generate readings, and
a classification engine to retrieve the stored weights from the memory structure and adjust the readings from the plurality of digital temperature sensors based on the weights and electrical parameters associated with the semiconductor apparatus.

8. The semiconductor apparatus of claim 7, wherein the electrical parameters and the plurality of digital temperature sensors are to be uncalibrated.

9. The semiconductor apparatus of claim 7, wherein the logic further includes a plurality of intra-die variation (IDV) probes to generate one or more of the electrical parameters.

10. The semiconductor apparatus of claim 9, wherein one or more of the plurality of IDV probes are positioned adjacent to one or more of the plurality of digital temperature sensors.

11. The semiconductor apparatus of claim 7, wherein the classification engine is further to:
train the ML model to obtain the weights; and
store the weights to the memory structure.

12. The semiconductor apparatus of claim 7, wherein the memory structure includes fuses.

13. The semiconductor apparatus of claim 7, wherein the memory structure includes a read-only memory.

14. The semiconductor apparatus of claim 7, wherein the logic coupled to the one or more substrates includes transistor channel regions that are positioned within the one or more substrates.

15. A method comprising:
generating, by a plurality of digital temperature sensors in a chip, readings;
retrieving, by a classification engine in the chip, stored weights associated with a machine learning (ML) model from a memory structure in the chip; and
adjusting, by the classification engine, the readings from the plurality of digital temperature sensors based on the weights and electrical parameters associated with the chip.

16. The method of claim 15, wherein the electrical parameters and the plurality of digital temperature sensors are uncalibrated.

17. The method of claim 15, further including generating, by a plurality of intra-die variation (IDV) probes, one or more of the electrical parameters.

18. The method of claim 17, wherein one or more of the plurality of IDV probes are positioned adjacent to one or more of the plurality of digital temperature sensors.

19. The method of claim 15, further including:
training, by the classification engine, the ML model to obtain the weights; and
storing, by the classification engine, the weights to the memory structure.

20. The method of claim 15, wherein the memory structure includes one or more of fuses or a read-only memory.
